(19) United States
(12) Patent Application Publication
(10) Pub. No.: US 2026/0075788 A1
(43) Pub. Date: Mar. 12, 2026

(54) TRAY SYSTEM FOR ELECTRONIC COMPONENTS AND TRAY STRUCTURE THEREOF

(71) Applicant: ILLINOIS TOOL WORKS INC., Glenview, IL (US)

(72) Inventor: Hong Yung BEE, Penang (MY)

(21) Appl. No.: 19/322,387

(22) Filed: Sep. 8, 2025

(30) Foreign Application Priority Data
Sep. 11, 2024 (MY) PI2024005273

(51) Int. Cl. H05K 13/00

(52) U.S. Cl. CPC H05K 13/0069

(57) ABSTRACT

The present disclosure provides a tray structure comprising one or more pockets, each pocket configured to receive a package assembly having a substrate or to receive a substrate, each pocket comprising: a plurality of captures configured to be in contact with side surfaces of the substrate; and a support portion configured to support the substrate, wherein the captures and the support portion form a receiving space to receive at least a part of the substrate, the captures are configured to be in contact with parts of the side surfaces of the substrate above lower edge portions thereof, and the support portion is configured to be in contact with a part of a bottom surface of the substrate but not in contact with an outer edge portion of the bottom surface of the substrate.

### RELATED APPLICATIONS

The present application claims the benefit of Malaysian (MY) Patent Application No. PI2024005273, filed September 11, 2024. The entirety of Malaysian (MY) Patent Application No. PI2024005273 is expressly incorporated herein by reference.

### TECHNICAL FIELD

The present disclosure relates to a tray structure, and in particular to a tray structure for receiving a package assembly having a substrate or for receiving a substrate.

### BACKGROUND

Tray structures are commonplace in the semiconductor industries for transporting components, such as, electronic components.

Substrates are the basic materials for manufacturing printed boards (e.g., PCBs). In the manufacture of single-sided and double-sided printed boards, hole drilling, chemical copper plating, copper electroplating, etching and other processes are selectively performed on the substrate to obtain a required circuit pattern. In the manufacture of another type of multi-layer printed boards, with the substrate as the base, a conductive pattern layer and a prepreg are alternately laminated and bonded together in one step, to form a multi-layer conductive pattern layer interconnection. The substrate has three functions of conduction, insulation and support. The performance, quality, processability in manufacturing, manufacturing cost, manufacturing level, etc. of the printed boards depend to a large extent on the substrate.

### SUMMARY OF THE DISCLOSURE

The most common use of the tray structures is in transporting and protecting the components through the stages of assembly, test and distribution. Each tray structure contains one or more pockets, each of which is designed to receive a component. The components comprise a package assembly, such as, an integrated circuit chip, having a substrate or a substrate.

The size of the pocket of the tray structure must conform as closely as possible to the size of the component that the pocket is designed to carry. In this way, the free movement of the component is reduced in both horizontal and vertical directions, preventing damage to the component. However, in order to accommodate manufacturing tolerances of the components and the tray structures, the pockets are designed to be slightly larger than the components that the pockets are designed to carry. There should be free play between the component and inner walls of the pocket.

The inventor has found that a package assembly having a substrate or a substrate is received in a pocket of a tray structure by close loose-fitting. The pocket includes a capture and a support portion. The capture and the support portion form a receiving space to receive at least a part of the package assembly having a substrate or the substrate. The support portion is configured to be in contact with a bottom surface of the substrate to support the substrate. The capture is configured to be in contact with a side surface of the substrate to limit the movement of the substrate along a surface of the support portion that supports the substrate.

The inventor has also found that an inner wall of the capture for contacting a side surface of the substrate intersects with and is connected to a support contact surface of the support portion for contacting a bottom surface of the substrate, to surround at least a part of an outer edge portion of the bottom of the substrate. As the substrate moves along the support contact surface of the support portion in the receiving space, the outer edge portion of the bottom of the substrate will occasionally come into contact with a lower edge portion of the inner wall and an outer edge portion of the support contact surface. However, the outer edge portion of the bottom of the substrate is very delicate, so the movement of the substrate in the receiving space formed by the capture and the support portion will often cause chip chip-off, scratches, etc. on the substrate.

In order to address the above problems, the present disclosure provides a tray structure comprising one or more pockets, each of which forms a receiving space to receive at least a part of the substrate. The pocket is configured to be not in contact with an outer edge portion of the bottom of the substrate when the substrate is received in the receiving space and the substrate moves along a surface which supports the substrate in the receiving space. The substrate in the present disclosure includes a general substrate and other different types of substrate, such as, silicon substrate, organic substrate, or glass substrate, etc.

Specifically, according to one aspect of the present disclosure, the present disclosure provides a tray structure comprising one or more pockets, each of which is configured to receive a package assembly having a substrate or to receive a substrate. Each pocket comprises a plurality of captures and a support portion. The plurality of captures are configured to be in contact with side surfaces of the substrate. The support portion is configured to support the substrate. The captures and the support portion form a receiving space to receive at least a part of the substrate. The captures are configured to be in contact with parts of the side surfaces of the substrate above lower edge portions thereof, and the support portion is configured to be in contact with a part of a bottom surface of the substrate but not in contact with an outer edge portion of the bottom surface of the substrate.

According to the one aspect of the present disclosure, the captures include inner walls configured to be in contact with the side surfaces of the substrate. Lower edges of the inner walls are higher than a surface of the support portion that supports the substrate.

According to the one aspect of the present disclosure, the support portion includes a support contact surface configured to be in contact with a part of the bottom surface of the substrate. An outer edge of the support contact surface is located closer to a center of the receiving space than the inner walls.

According to the one aspect of the present disclosure, the captures and the support portion are configured such that when the substrate moves in the receiving space along a surface of the support portion that supports the substrate until one of the captures comes into contact with a first side surface of the substrate and another of the captures is separated from a second side surface of the substrate opposite to the first side surface, the support portion is still not in contact with the outer edge portion of the bottom surface of the substrate.

According to the one aspect of the present disclosure, a side surface of the support portion is in the shape of a slope.

According to the one aspect of the present disclosure, the support portion is made of a soft or hard material.

According to the one aspect of the present disclosure, the support portion is a support frame configured to be in contact with a peripheral portion of the bottom surface of the substrate to support the substrate. Alternatively, the support portion is a support floor configured to be in contact with substantially the entire bottom surface of the substrate to support the substrate.

According to the one aspect of the present disclosure, the support frame comprises a plurality of projection portions which are disposed along a circumferential direction and separated from the plurality of captures along the circumferential direction.

According to the one aspect of the present disclosure, the tray structure further includes a mounting frame. The plurality of captures and the support portion are mounted on the mounting frame.

According to another aspect of the present disclosure, the present disclosure provides a tray system comprising one or more tray structures as discussed above.

According to the another aspect of the present disclosure, the tray structures are stacked on top of one another.

### BRIEF DESCRIPTION OF THE DRAWINGS

The accompanying drawings are not drawn to scale. In the accompanying drawings, each identical or nearly identical component denoted in different figures is denoted by the same reference sign. For the sake of clarity, not every component may be labeled in every figure. In the figures:

FIG. 1A shows a perspective view of a tray structure of the present disclosure, in which a package assembly having a substrate is received;

FIG. 1B is a perspective view of a first embodiment of a tray structure of the present disclosure, in which no package assembly or substrate is received;

FIG. 1C shows a perspective view of a second embodiment of a tray structure of the present disclosure;

FIG. 1D is a top view of FIG. 1C;

FIG. 1E shows a perspective view of a third embodiment of a tray structure of the present disclosure;

FIG. 1F shows a perspective view of a fourth embodiment of a tray structure of the present disclosure;

FIG. 1G shows a perspective view of a fifth embodiment of a tray structure of the present disclosure;

FIG. 1H is a top view of FIG. 1G;

FIG. 1I shows a perspective view of an embodiment of a tray system having tray structures of the present disclosure;

FIG. 2A is a partially enlarged view of the tray structure, in which a package assembly having a substrate is received, shown in FIG. 1A when viewed from a first angle;

FIG. 2B is a partially enlarged view of the tray structure, in which a package assembly having a substrate is received, shown in FIG. 1A when viewed from a second angle;

FIG. 2C is a partially enlarged view of the tray structure, in which a package assembly having a substrate is received, shown in FIG. 1A when viewed from a third angle;

FIG. 2D is a partially enlarged view of the tray structure, in which a package assembly having a substrate is received, shown in FIG. 2C;

FIG. 3A is a partially enlarged view of the tray structure shown in FIG. 1C when viewed from a first angle;

FIG. 3B is a partially enlarged view of the tray structure shown in FIG. 1C when viewed from a second angle;

FIG. 4A is a partially enlarged sectional view, taken along a section line A-A, of the tray structure shown in FIG. 1C;

FIG. 4B is a partially enlarged sectional view, taken along a section line B-B, of the tray structure shown in FIG. 1C;

FIG. 5A shows a sectional view of the second embodiment of a tray structure of the present disclosure after movement of a package assembly having a substrate;

FIG. 5B is a first partially enlarged view of the tray structure shown in FIG. 5A; and

FIG. 5C is a second partially enlarged view of the tray structure shown in FIG. 5A.

### DETAILED DESCRIPTION OF EMBODIMENTS

Various specific implementations of the present disclosure are described below with reference to the drawings which constitute part of this specification. It is to be understood that although the terms indicating orientations, such as “front”, “rear”, “upper”, “lower”, “left”, “right”, “top” and “bottom”, are used in the present disclosure to describe structural parts and elements in various examples of the present disclosure, these terms are used herein only for ease of illustration and are determined based on the example orientations as shown in the accompanying drawings. Since the arrangements in the embodiments disclosed in the present disclosure may be in various directions, these terms indicating directions are only illustrative and should not be considered as limitations.

The ordinal numbers such as “first” and “second” used in the present disclosure are merely used for distinguishing and identification, and do not have any other meanings. Unless otherwise specified, the ordinal numbers neither indicate a specific order, nor have a specific relevance.

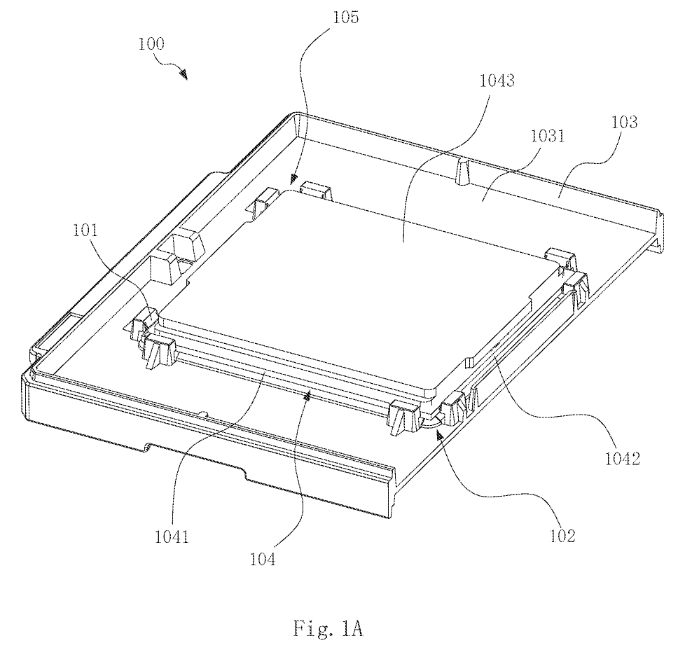

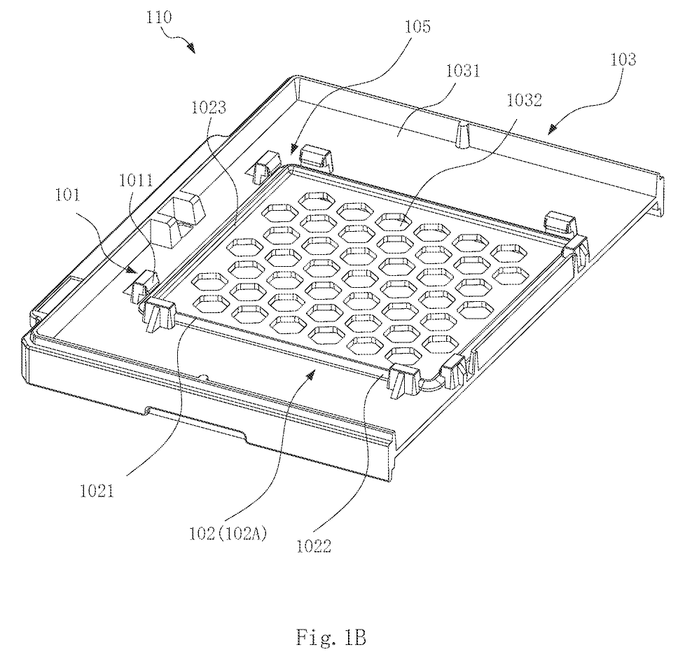

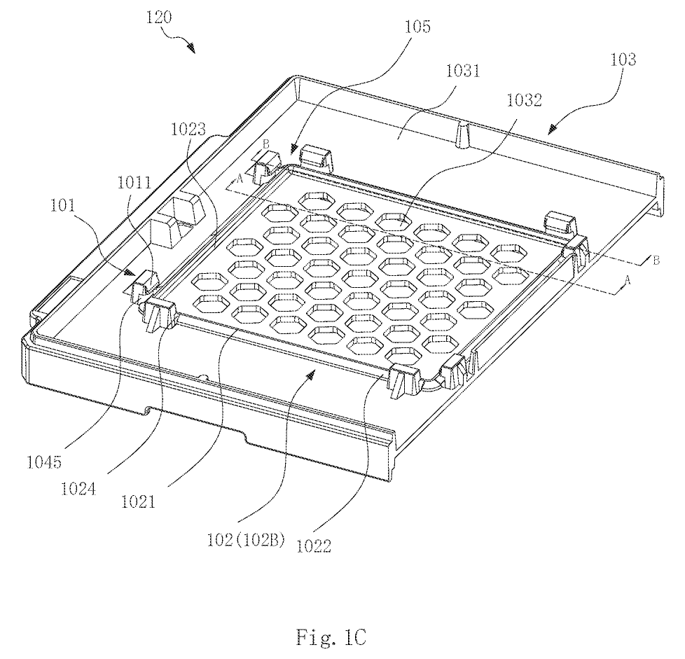

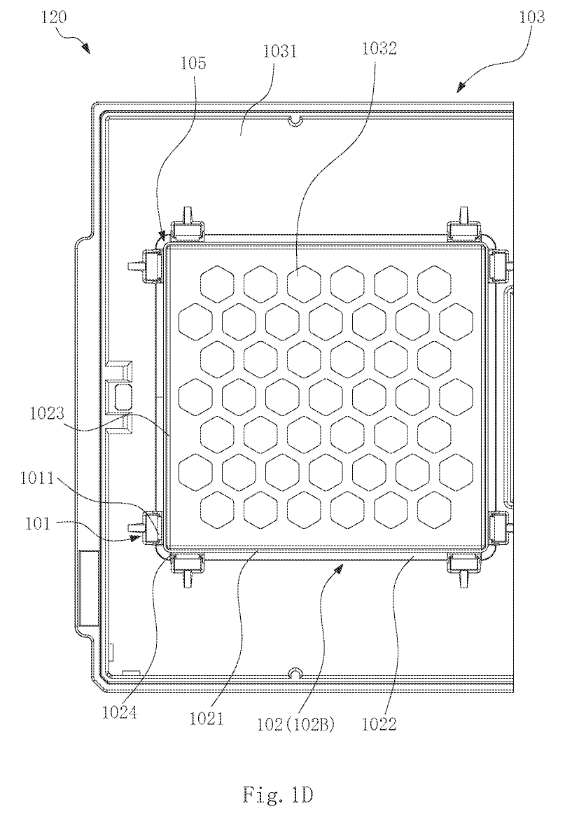

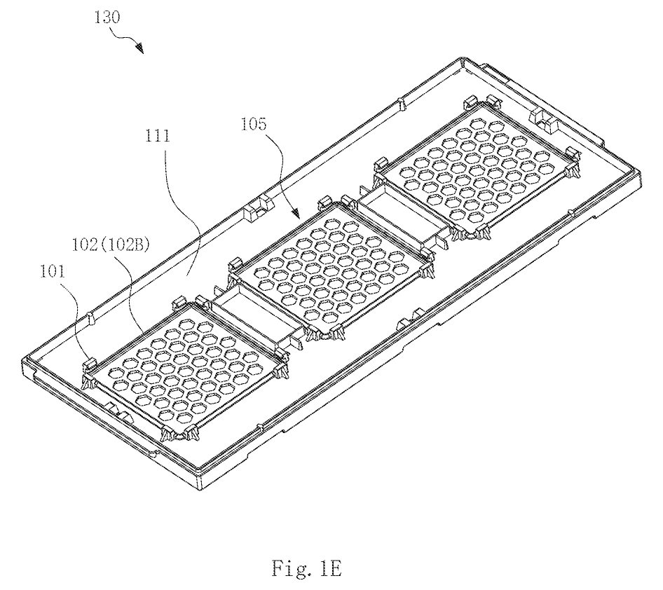

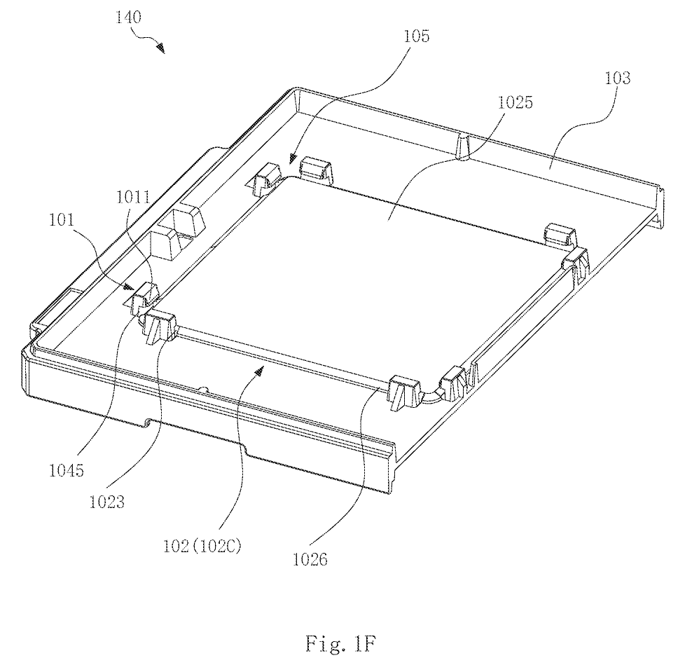

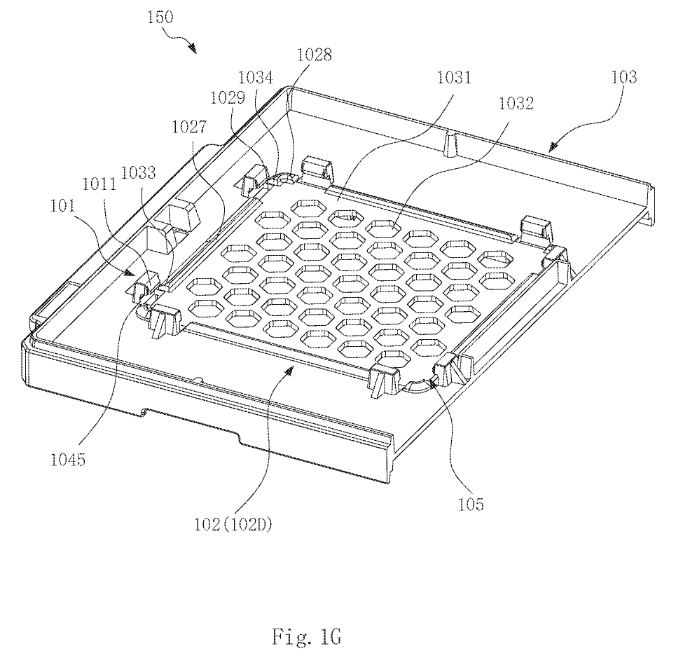

FIG. 1A shows a perspective view of a tray structure 100 of the present disclosure, in which a package assembly 1043 having a substrate 104 at the bottom is received, to show mating relationships of the tray structure 100 and its components with the package assembly 1043 and the substrate 104. FIG. 1B shows a perspective view of a first embodiment of a tray structure of the present disclosure, in which no package assembly or substrate is received, FIG. 1C shows a perspective view of a second embodiment of a tray structure of the present disclosure, FIG. 1D is a top view of FIG. 1C, FIG. 1E shows a perspective view of a third embodiment of a tray structure of the present disclosure, FIG. 1F shows a perspective view of a fourth embodiment of a tray structure of the present disclosure, FIG. 1G shows a perspective view of a fifth embodiment of a tray structure of the present disclosure, FIG. 1H is a top view of FIG. 1G, and FIG. 1I shows a perspective view of an embodiment of a tray system having tray structures of the present disclosure, to show various implementations and structures of the tray structure and the tray system of the present disclosure. For the convenience of illustration and description, the orientations of “upper”, “lower”, “top” and “bottom” in the following description of the present disclosure make reference to “upper”, “lower”, “top” and “bottom” of the tray structure 100 shown in FIG. 1A.

As shown in FIG. 1A, the package assembly 1043 having the substrate 104 is received in the tray structure 100. The tray structure 100 includes one pocket, which is configured to receive the package assembly 1043 having the substrate 104. The package assembly 1043 includes a plurality of layers, including a bottom layer, i.e., the substrate 104, located at the bottom. The pocket comprises a plurality of captures 101 and a support portion 102. The plurality of captures 101 and the support portion 102 form a receiving space 105 to receive at least a part of the substrate 104. In another embodiment, the pocket of the tray structure 100 is configured to receive the substrate 104. FIG. 1A shows that the entire substrate 104 is received in the receiving space 105. In other embodiments, the tray structure may receive a part of the substrate.

The length and width of the receiving space 105 formed by the captures 101 and the support portion 102 of the pocket of the tray structure 100 are slightly larger than the length and width of the package assembly 1043 having the substrate 104 at the bottom, respectively, to enable the package assembly 1043 to be easily loaded in the receiving space 105 and unloaded from the receiving space 105, and to allow for a certain dimension variance of the length and width of the receiving space 105 and the package assembly 1043. The above arrangement of the tray structure 100 can also avoid damage, such as chip-off, scratches, etc., to edge portions of the bottom of the substrate 104 at the bottom of the package assembly 1043 due to coming into contact with the captures 101 and/or the support portion 102, or moving along the captures 101 and/or the support portion 102 during loading (e.g., when inserting the package assembly 1043 into the receiving space 105) and unloading. The edge portions of the bottom of the substrate 104 include lower edge portions of side surfaces and an outer edge portion of a bottom surface of the substrate 104. When the package assembly 1043 is received in the receiving space 105, the edge portions of the bottom of the substrate 104 at the bottom of the package assembly 1043 may also be damaged due to contacting with the captures 101 and/or the support portion 102.

After the package assembly 1043 is received in the receiving space 105, during use (e.g., transporting) or in other applications, the package assembly 1043 may move along the support contact surface 1021 of the support portion 102, which may also cause damage to the edge portions of the bottom of the substrate 104 due to contacting with the captures 101 and/or the support portion 102. Therefore, in order to address the above problems, in the present disclosure, the captures 101 are configured to be not in contact with the lower edge portions of the side surfaces of the substrate 104, and the support portion 102 is configured to be not in contact with the outer edge portion of the bottom surface of the substrate 104, for avoiding damage, such as chip-off, scratches, etc., to the edge portions of the bottom of the substrate 104 due to contacting with the captures 101 and/or the support portion 102.

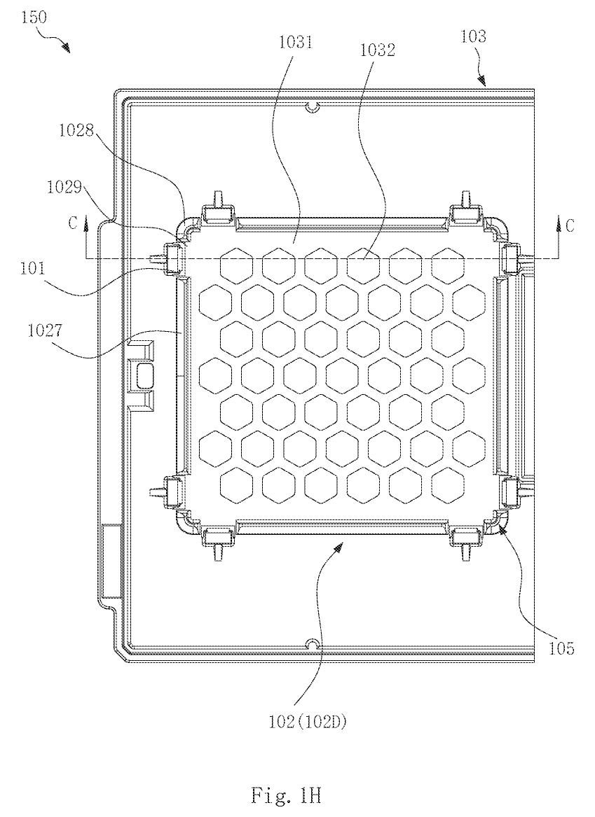

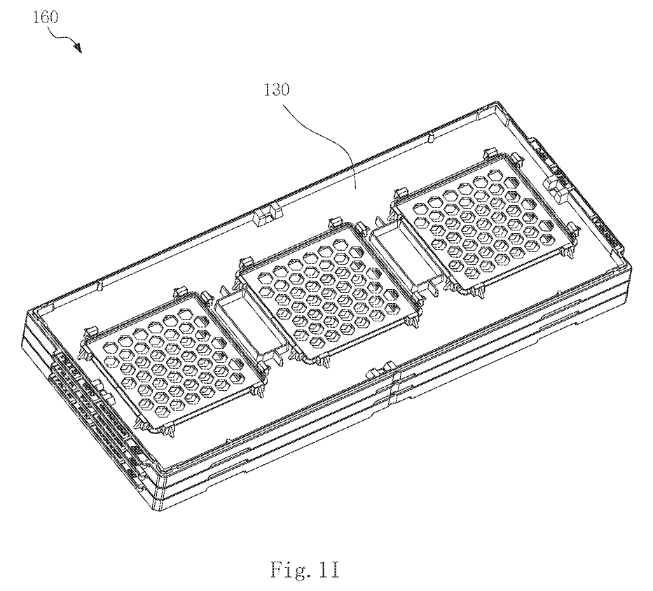

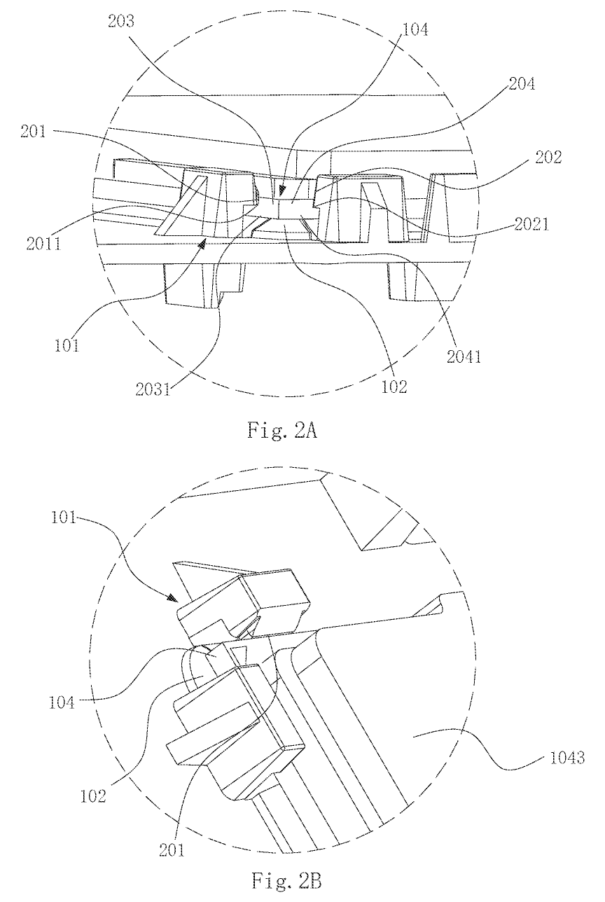

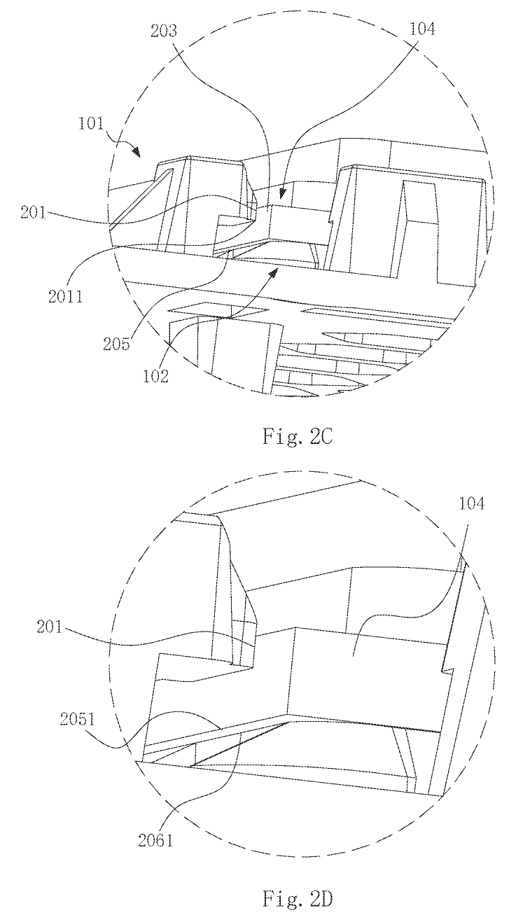

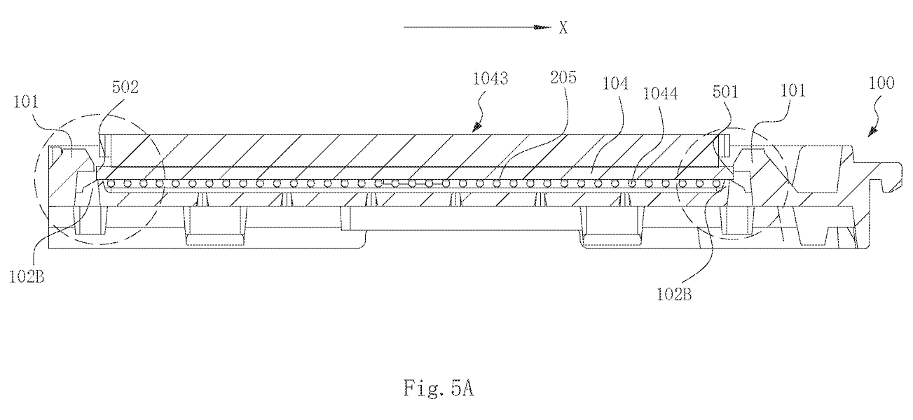

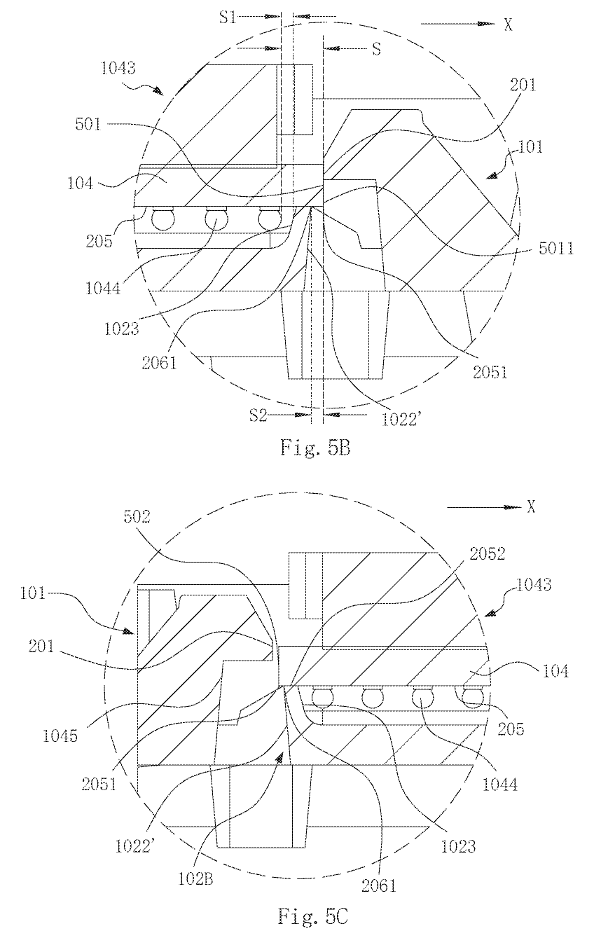

As shown in FIG. 1A, the plurality of captures 101 are configured to be in contact with the side surfaces of the substrate 104. The side surfaces of the substrate 104 include side surfaces 1041, 1042 shown in FIG. 1A, and two side surfaces (not shown) opposite to the two side surfaces 1041, 1042. More specifically, the captures 101 are configured to be in contact with parts of the side surfaces 1041, 1042 of the substrate 104, but not in contact with the lower edge portions 2031, 2041 (see FIG. 2A) of the side surfaces of the substrate 104. For example, the captures 101 are configured to be in contact with parts of the side surfaces of the substrate 104 above the lower edge portions 2031, 2041, for avoiding damage to the lower edge portions 2031, 2041 of the side surfaces of the substrate 104 due to contacting with the captures 101 during use (e.g., transporting) or in other applications. In an embodiment, for a BGA type substrate package assembly, the bottom surface 205 of the substrate 104 is arranged with a plurality of solder balls (see FIGS. 5A-5C), which are, for example, arranged in a matrix. In other embodiments, the bottom surface 205 of the substrate 104 is arranged with other suitable structures. For example, for a LGA type substrate package assembly, the bottom surface 205 of the substrate 104 is arranged with a plurality of land pads (not shown).

The support portion 102 is configured to support the substrate 104. The support portion 102 is in contact with a part of the bottom surface 205 of the substrate 104 to support the substrate 104. The support portion 102 is not in contact with the outer edge portion 2051 of the bottom surface 205 of the substrate 104 (see FIGS. 2C-2D), for avoiding damage to the lower edge portions 2031, 2041 of the side surfaces of the substrate 104 due to contacting with the captures 101 during use (e.g., transporting) or in other applications. The lower edge portions 2031, 2041 of the side surfaces of the substrate 104 are located near the bottom surface 205 of the substrate 104 (see FIGS. 2A and 2C). The parts of the side surfaces of the substrate 104 above the lower edge portions 2031, 2041 represent parts of the side surfaces of the substrate 104 that are adjacent to the lower edge portions 2031, 2041 and away from the bottom surface 205 of the substrate 104.

As shown in FIG. 1A, the pocket of the tray structure 100 includes eight captures 101. The eight captures 101 form four pairs of captures 101 respectively arranged to be in contact with or adjacent to parts of four side surfaces of the substrate 104. In other embodiments, the pocket of the tray structure 100 includes captures 101 with other appropriate number and on appropriate locations, to be in contact with or adjacent to parts of the four side surfaces of the substrate 104. The tray structure 100 further includes a mounting frame 103. The captures 101 and the support portion 102 are both mounted to the mounting frame 103. The mounting frame 103 is in the shape of a groove and includes a floor 1031. The captures 101 and the support portion 102 are mounted on the floor 1031. The floor 1031 includes through holes 1032 (see FIGS. 1B-1E and FIGS. 1G-1H) configured to allow an airflow to pass therethrough to cool the substrate 104 received by the captures 101 and the support portion 102. In other embodiments, the mounting frame 103 includes other suitable structures.

FIG. 1B shows a first embodiment of a tray structure of the present disclosure, i.e., a tray structure 110. The tray structure 110 of FIG. 1B is a specific embodiment of the tray structure 100 of FIG. 1A. The above descriptions of the tray structure 100 with reference to FIG. 1A can also apply to the tray structure 110 of FIG. 1B, and thus is not repeated herein.

As shown in FIG. 1B, the support portion 102 of the pocket of the tray structure 110 is called a support portion 102A. The support portion 102A is a support frame configured to be in contact with a peripheral portion of the bottom surface 205 of the substrate 104 to support the substrate 104, but not to be in contact with the outer edge portion 2051 of the bottom surface 205 of the substrate 104 (see FIGS. 2C-2D). The support frame and the floor 1031 of the tray structure 110 form a space for receiving the solder balls, land pads, and other structures arranged on the bottom surface 205 of the substrate 104. The floor 1031 of the tray structure 110 does not contact the solder balls, land pads, and other structures arranged on the bottom surface 205 of the substrate 104 in order to avoid damage, such as chip-off, scratches, etc., to these structures on the bottom surface 205 of the substrate 104 due to contact. This support frame structure of the support portion 102 allows the support portion 102 to be made of a soft material or a hard material. This support frame structure made of a rigid material does not cause damage to the outer edge portion 2051 of the bottom surface 205 of the substrate 104 because the support frame structure does not contact the outer edge portion 2051 of the bottom surface 205 of the substrate 104, and does not cause damage to structures on the bottom surface 205 of the substrate 104, such as solder balls, land pads, and the like, because the support frame structure does not contact these structures on the bottom surface 205 of the substrate 104. In an embodiment, the rigid material is less costly compared to the soft material. Structures made of rigid materials have a greater ability to withstand pressure and have a longer service life than those made of soft materials.

As shown in FIG. 1B, the support frame 102A is a protrusion, which extends along a circumferential direction and is closed. A top surface 1021 of the protrusion extends along the circumferential direction to contact the peripheral portion of the bottom surface 205 of the substrate 104 for supporting the substrate 104. The top surface 1021 has substantially the same height along the circumferential direction. In an embodiment, the top surface 1021 (i.e., support surface) is part of a support plane. The outer surface 1022 of the protrusion away from the receiving space 105 includes a surface in the shaped of a slope. The inner surface 1023 of the projection facing the receiving space 105 is recessed towards the outer surface 1022. In an embodiment, the inner surface 1023 comprises a curved surface. The inner surface 1023 of the pocket and the floor 1031 of the tray structure 110 form a space for receiving solder balls, land pads, and other structures arranged on the bottom surface 205 of the substrate 104. In other embodiments, the support frame 102A includes other suitable structures. The capture 101 of the pocket of the tray structure 110 is in an inverted L-shape. The capture 101 comprises a projection portion 1011 arranged at an upper part of the capture 101 and facing the holding space 105. The projection portion 1011 comprises inner walls 201, 202 configured to contact a part of a side surface of the substrate 104 but not to contact a lower edge portion of the side surface of the substrate 104 (see FIGS. 2A-2D). In other embodiments, the support portion 102 of the pocket of the tray structure of the present disclosure includes other suitable structures. For example, in an embodiment, the support portion 102 is composed of a plurality of protrusions which are separated from each other.

In an embodiment, the tray structure is formed in one piece. One way of forming the one-piece is injection moulding to form the one-piece. In an embodiment, a male injection mold and a female injection mold are combined together, a material is injected into the combined male and female injection molds, and the male and female injection molds are removed after the material has been moulded, thereby forming the tray structure of the present disclosure. In order to facilitate injection moulding of the one-piece tray structure, a second embodiment of the tray structure, i.e., a tray structure 120, is designed in the present disclosure. FIG. 1C shows a perspective view of the tray structure 120, and FIG. 1D shows a top view of the tray structure 120.

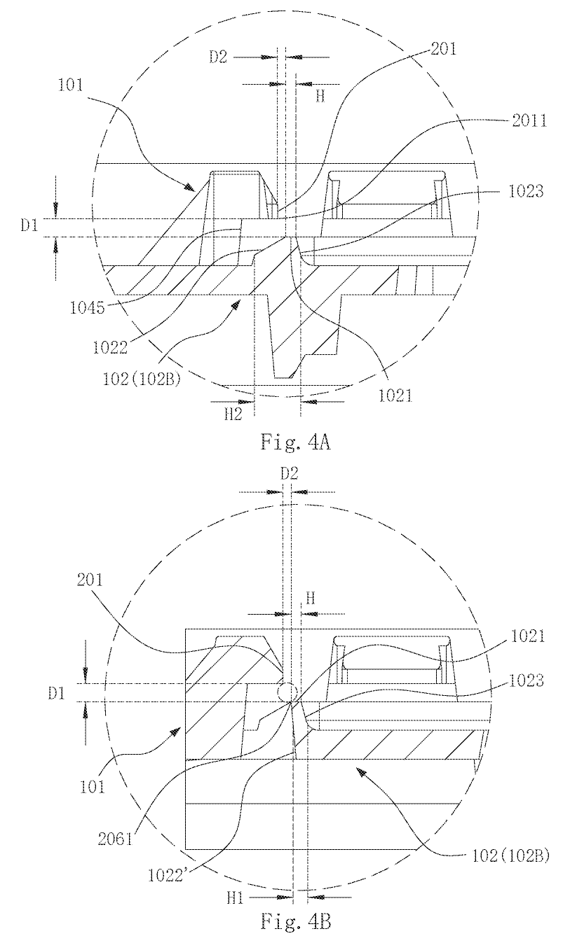

The tray structure 120 in FIGS. 1C-1D has substantially the same structure as the tray structure 110 in FIG. 1B. The difference is that the tray structure 120 in FIGS. 1C-1D is obtained by removing a part from the tray structure 110 in FIG. 1B. Specifically, parts of the support portion 102 of the pocket and the floor 1031 of the mounting frame 103 below the projection portion 1011 of the capture 101 of the pocket are removed from the tray structure 110 in FIG. 1B to obtain the tray structure 120 in FIGS. 1C-1D. In addition, in order to reliably injection mould to form the one-piece, the removed parts extend further towards the interior of the receiving space 105 of the pocket with respect to the projection portion 1011. As shown in FIGS. 1C-1D, the support portion 102 in the tray structure 120 is a support portion 102B. The above-described removal causes the support portion 102B to comprise a portion having a depression 1024. On the same side of the tray structure, in the direction perpendicular to the inner wall 201 of the capture 101, the depression 1024 faces the corresponding capture 101. The outer surface of the portion is an outer surface 1022’ (see FIG. 4B and FIGS. 5B-5C). The outer surface 1022’ is a slope inclined towards the receiving space 105 in a top-to-bottom direction to facilitate removal of the injection molds after injection moulding of the tray structure. On the same side of the tray structure, in the direction perpendicular to the inner wall 201 of the capture 101, the capture 101 has a corresponding inner surface 1045 facing the outer surface 1022’. The inner surface 1045 is a slope inclined away from the receiving space 105 in a top-to-bottom direction to assist in removal of the injection molds after injection moulding of the tray structure.

As can be seen above, in the portion of the support portion 102B having the depression 1024 facing the capture 101, the support frame has a smaller wall thickness H1 between the inner surface 1023 and the outer surface 1022’ thereof (see FIGS. 4A-4B). In other portions of the support portion 102B (which do not have the depression 1024), the support frame has a larger wall thickness H2 between the inner surface 1023 and the outer surface 1022 thereof (see FIGS. 4A-4B). This arrangement of the tray structure 120 in FIGS. 1C-1D helps to meet the 2-plate mould technology design of existing injection molds, to reduce manufacturing and mold costs as well as to optimize possible process cycle time, and so on. In other embodiments, the tray structure 120 of FIGS. 1C-1D includes other suitable structures. The same structures in the tray structure 120 of FIGS. 1C-1D as in the tray structure 110 of FIG. 1B are not repeated herein.

FIGS. 1A-1D show a tray structure comprises one pocket configured to receive a single package assembly 1043 having a substrate 104 or to receive a single substrate 104. In other embodiments, the tray structure comprises more pockets (such as, as shown in FIG. 1E), each of which is configured to receive a package assembly 1043 having a substrate 104 or to receive a substrate 104.FIG. 1E shows the third embodiment of the tray structure of the present disclosure, namely, a tray structure 130. The tray structure 130 comprises three pockets, such as, each pocket is that of the tray structure 120 shown in FIG. 1C. Three pockets form three receiving spaces 105. Each receiving space 105 of each pocket is configured to receive at least a part of one package assembly having a substrate or one substrate. The tray structure 130 includes a mounting frame 111. The captures 101 and the support portions 102B of each pocket are both mounted to the mounting frame 111. In other embodiments, the tray structure 130 includes other appropriate number of pockets which are, for example, arranged in a matrix. In an embodiment, the tray structure is a Matrix tray, such as a JEDEC Shipping and Handling Matrix Tray, for receiving or storing a plurality of the package assemblies or a plurality of the substrates.

FIG. 1F shows the fourth embodiment of the tray structure of the present disclosure, namely, a tray structure 140. The tray structure 140 in FIG. 1F has substantially the same structure as the tray structure 120 in FIG. 1C. The difference is that the support portion 102B of the pocket of the tray structure 120 in FIG. 1C is a support frame, while the support portion 102C of the pocket of the tray structure 140 in FIG. 1F is a support floor. The support floor 102C is configured to be in contact with substantially the entire bottom surface of the substrate 104 to support the substrate 104, but not in contact with the outer edge portion 2051 of the bottom surface 205 of the substrate 104. As aforementioned, the bottom surface 205 of the substrate 104 is provided with solder balls (see FIGS. 5A-5C), contacts, and other structures. Therefore, when the package assembly 1043 having the substrate 104 or the substrate 104 is received in the tray structure 140 in FIG. 1F, the support floor 102C of the tray structure 140 contacts the solder balls, land pads, and other structures arranged on the bottom surface 205 of the substrate 104. In order to avoid damage to the structures on the bottom surface 205 of the substrate 104 caused by contacting these structures, such as causing chip-off, scratches, and the like to the structures, the support floor 102C (i.e., the support portion) is made of a soft material.

As shown in FIG. 1F, the support floor 1022 is a boss. The boss has a top surface 1025 configured to be in contact with substantially the entire bottom surface of the substrate 104 to support the substrate 104. In an embodiment, the top surface 1025 (i.e., support surface) is a support plane. A side surface 1026 of the boss has substantially the same shape as the outer surfaces 1022, 1022’ of the support frame 102B in FIG. 1C. In other embodiments, the support floor 102C includes other suitable structures. The same structures in the tray structure 140 of FIG. 1F as in the tray structure 120 of FIG. 1C are not repeated herein.

FIGS. 1G-1H show the fifth embodiment of a tray structure of the present disclosure, namely, a tray structure 150. The tray structure 150 in FIGS. 1G-1H has substantially the same structure as the tray structure 120 in FIGS. 1C-1D. The difference is that the support portion 102B of the pocket of the tray structure 120 in FIGS. 1C-1D is a circumferentially extending and closed projection having a corresponding depression 1024 facing the capture 101, whereas the support portion 102D of the pocket of the tray structure 150 in FIGS. 1G-1H consists of a plurality of projections or projection portions 1027, 1028 that are separated from each other. These projections 1027, 1028 in FIGS. 1G-1H may be obtained by further removing from the tray structure 120 in FIGS. 1C-1D a portion of the support portion 102B facing the capture 101 in the direction perpendicular to the inner wall 201 of the capture 101, on the same side of the pocket of the tray structure. The top surfaces of the projections 1027, 1028 of the support portion 102D are parts of the top surface 1021 (i.e., the support contact surface) of the support portion 102B.

As shown in FIGS. 1G-1H, the pocket of the tray structure 150 includes a plurality of captures 101 and a support portion 102D forming a receiving space 105. The projections 1027, 1028 of the support portion 102D extend along a circumferential direction. The projections 1027, 1028 and the plurality of captures 101 are disposed spaced apart along the circumferential direction. In an embodiment, adjacent projections 1027, 1028 are spaced apart by an opening 1029 along the circumferential direction. The captures 101 are at least partially disposed at the opening 1029 along the circumferential direction.

The projection 1027 extends substantially linearly on one side of the pocket of the tray structure 150. For example, the projection 1027 is disposed between two captures 101 on one side of the pocket of the tray structure 150. The projection 1028 extends curvedly from one side of the pocket of the tray structure 150 to the other side thereof. For example, the projection 1028 is disposed between two captures 101 that are on different sides of the pocket of the tray structure 150 and adjacent to each other. In order to avoid damage to the bottom of the substrate 104 during loading and unloading of the package assembly 1043 having the substrate 104 or the substrate 104, the end portion of the projection 1027 of the support portion 102D along the circumferential direction includes a curved surface structure 1033, and the end portion of the projection 1028 thereof along the circumferential direction includes a curved surface structure 1034. In an embodiment, the curved surface structures 1033, 1034 may be formed by chamfering. In other embodiments, the ends of the projections 1027, 1028 along the circumferential direction include other suitable structures. The support portion 102D includes other suitable raised structures. The support portion 102D of the pocket of the tray structure 150 of FIGS. 1G-1H facilitates to meet injection moulding material DFM guidelines to reduce process FMEA risk, as detailed in the specific description below. The same structures in the tray structure 150 of FIGS. 1G-1H as the tray structure 120 of FIGS. 1C-1D are not repeated herein.

FIG. 1I shows a perspective view of an embodiment of a tray system 160 having tray structures of the present disclosure. As shown in FIG. 1I, the tray system 160 comprises three tray structures stacked on top of one another. In an embodiment, the tray system 160 comprises three tray structures 130 shown in FIG. 1E. In other embodiments, the tray system 160 comprises other appropriate tray structures, such as, the tray structure 110120, 140, 150, or comprises other tray structures with other appropriate number of pockets. In other embodiments, the tray system 160 comprises other appropriate number of tray structures stacked on top of one another.

FIG. 2A is a partially enlarged view of the tray structure 100, in which a package assembly 1043 having a substrate 104 is received, shown in FIG. 1A when viewed from a first angle, FIG. 2B is a partially enlarged view of the tray structure 100, in which a package assembly 1043 having a substrate 104 is received, shown in FIG. 1A when viewed from a second angle, FIG. 2C is a partially enlarged view of the tray structure 100, in which a package assembly 1043 having a substrate 104 is received, shown in FIG. 1A when viewed from a third angle, and FIG. 2D is a partially enlarged view of the tray structure 100, in which a package assembly 1043 having a substrate 104 is received, shown in FIG. 2C, to show mating relationships of the captures 101 and the support portion 102 of the tray structure 100 with the substrate 104.

As described above, the captures 101 and the support portion 102 of the pocket of the tray structure 100 form a receiving space 105 to receive the package assembly 1043 having the substrate 104. As shown in FIGS. 2A-2D, the substrate 104 includes adjacent side surfaces 203, 204. The side surface 203 of the substrate 104 includes a lower edge portion 2031, and the side surface 204 of the substrate 104 includes a lower edge portion 2041. The substrate 104 further includes side surfaces (not shown) opposite to the side surfaces 203, 204, respectively. The substrate 104 further includes a bottom surface 205, which includes an outer edge portion 2051.

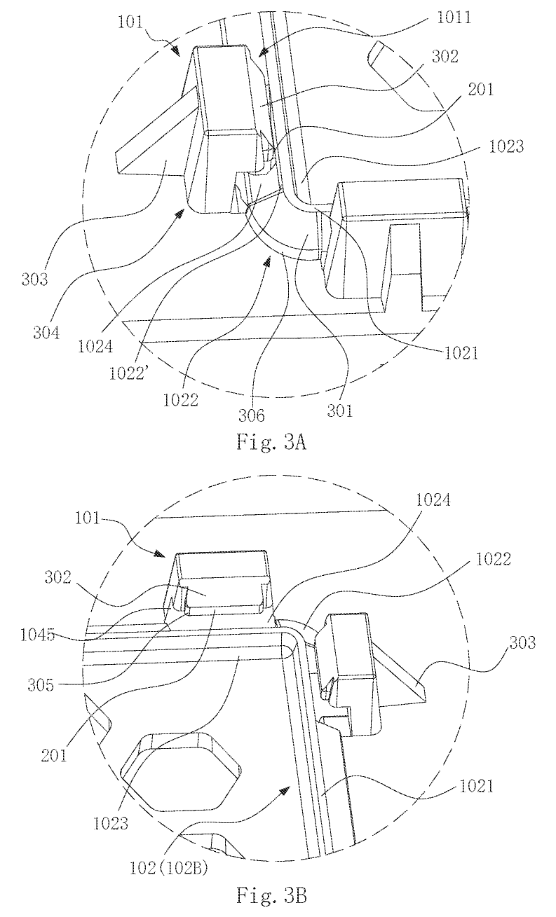

A capture 101 of the pocket of the tray structure 100 includes an inner wall 201 configured to be in contact with a part of the side surface 203 of the substrate 104 but not in contact with the lower edge portion 2031 of the side surface 203 of the substrate 104. For example, the inner wall 201 is in contact with a part of the side surface 203 of the substrate 104 above the lower edge portion 2031. The inner wall 201 includes a lower edge 2011, which is higher than the support contact surface 1021 of the support portion 102 (see FIGS. 3A-3B) in a direction perpendicular to the support contact surface 1021 of the support portion 102 (e.g., in a vertical direction), so that the lower edge 2011 is higher than the lower edge portion 2031 of the side surface 203 of the substrate 104 supported on the surface 1021 of the support portion 102, and the inner wall 201 is thus not in contact with the lower edge portion 2031 of the side surface 203 of the substrate 104.

Another capture 101 of the pocket of the tray structure 100 includes an inner wall 202 configured to be in contact with a part of the side surface 204 of the substrate 104 but not in contact with the lower edge portion 2041 of the side surface 204 of the substrate 104. For example, the inner wall 202 is in contact with a part of the side surface 204 of the substrate 104 above the lower edge portion 2041. The inner wall 202 includes a lower edge 2021, which is higher than the support contact surface 1021 of the support portion 102 (see FIGS. 3A-3B) in a direction perpendicular to the support contact surface 1021 of the support portion 102 (e.g., in a vertical direction), so that the lower edge 2021 is higher than the lower edge portion 2041 of the side surface 204 of the substrate 104 supported on the surface 1021 of the support portion 102, and the inner wall 202 is thus not in contact with the lower edge portion 2041 of the side surface 204 of the substrate 104. With such arrangement, the inner walls 201, 202 of the capture 101 are formed as elevated/suspended inner walls.

The support portion 102 of the pocket of the tray structure 100 includes the support contact surface 1021 (see FIGS. 3A-3B), which is configured to be in contact with a part of the bottom surface 205 of the substrate 104. As shown in FIGS. 2C-2D, the support contact surface 1021 includes an outer edge 2061, which is located closer to a center of the receiving space 105 than the inner wall 201 in a direction perpendicular to the inner wall 202 (e.g., in a horizontal direction), so that the outer edge 2061 is located away from the outer edge portion 2051 of the bottom surface 205 of the substrate 104 toward the center of the receiving space 105, and the support contact surface 1021 is thus not in contact with the outer edge portion 2051 of the bottom surface 205 of the substrate 104.

FIG. 3A is a partially enlarged view of the tray structure 120 shown in FIG. 1C when viewed from a first angle, and FIG. 3B is a partially enlarged view of the tray structure 120 shown in FIG. 1C when viewed from a second angle, to show respective structures of the captures 101 and the support portion 102(102B) of the tray structure 120.

As shown in FIGS. 3A-3B, the capture 101 of the pocket of the tray structure 120 includes a body portion 304 and a rib 303. The body portion 304 includes a projection portion 1011, which includes an inner wall 201 and a guide wall 302. The body portion 304 is in an inverted L-shape. The body portion 304 may include other suitable structures. The inner wall 201 is arranged to face the receiving space 105 formed by the captures 101 and the support portion 102(102B), and is configured to be in contact with a part of the side surface of the substrate 104 received in the receiving space 105. In an embodiment, the inner wall 201 is a vertical surface. In order to avoid damage to the bottom of the substrate 104 during loading and unloading of the package assembly 1043 having the substrate 104 or the substrate 104, the end portion of the inner wall 201 of the capture 101 includes a curved surface structure 305. The guide wall 302 is located adjacent to the inner wall 201. The guide wall 302 is configured to guide the loading of the package assembly 1043 and the substrate 104 to the receiving space 105. The guide wall 302 is arranged to face the receiving space 105, and is tilted gradually toward the receiving space 105 in the top-to-bottom direction.

When the package assembly 1043 having the substrate 104 or the substrate 104 is inserted from above the tray structure 120 into the receiving space 105 of the pocket, the guide walls 302 of the plurality of captures 101 form (enclose) a large opening to allow the package assembly 1043 and the substrate 104 to be easily loaded to the receiving space 105. After the package assembly 1043 and the substrate 104 pass through the large opening formed by the guide walls 302, the package assembly 1043 and the substrate 104 enter a small opening formed (enclosed) by the inner walls 201 of the plurality of captures 101 and comes into contact with the support portion 102(102B), so as to be received in the receiving space 105.

As shown in FIG. 1C, the support portion 102(102B) of the pocket of the tray structure 120 is a projection which extends along a circumferential direction. On the same side of the pocket of the tray structure, in the direction perpendicular to the inner wall 201 of the capture 101, the projection has corresponding depressions 1024 that face the captures 101. The support portion 102(102B) includes a support contact surface 1021, outer surfaces 1022, 1022’ and an inner surface 1023. The support contact surface 1021 is configured to be in contact with a part of the bottom surface 205 of the substrate 104 received in the receiving space 105. As shown in FIGS. 3A-3B, the support contact surface 1021 is a horizontal surface. The outer surfaces 1022, 1022’ of the support portion 102(102B) are located adjacent to the support contact surface 1021. The outer surface 1022 includes an upper portion 301 which is tilted gradually outward (away from the receiving space 105) in the top-to-bottom direction. A substantially vertical surface 306 is formed at the bottom of the outer surface 1022. The outer surface 1022’ is tilted gradually towards the receiving space 105 in the top-to-bottom direction. In other embodiments, the support portion 102(102B) includes other suitable structures, for example, including other suitable outer surfaces.

FIG. 4A is a partially enlarged sectional view, taken along a section line A-A, of the tray structure 120 shown in FIG. 1C, and FIG. 4B is a partially enlarged sectional view, taken along a section line B-B, of the tray structure 120 shown in FIG. 1C, to show mating relationships of the captures 101 and the support portion 102(102B) of the pocket of the tray structure 120. The section line A-A does not pass through the capture 101 and the portion of the support portion 102B having the depression 1024 facing the capture 101, while the section line B-B passes through the capture 101 and the portion of the support portion 102(102B) having the depression 1024 facing the capture 101.

As shown in FIG. 4A, the portion of the support portion 102B that does not have the depression 1024 facing the capture 101 includes a support contact surface 1021, an outer surface 1022, and an inner surface 1023. Such portion of the support portion 102B has a greater wall thickness H2 (i.e., a thickness between the outer surface 1022 and the inner surface 1023) because the outer surface 1022 includes an upper portion 301 which is tilted gradually away from the receiving space 105 in the top-to-bottom direction (see FIG. 3A). As shown in FIG. 4B, the portion of the support portion 102B having the depression 1024 facing the capture 101 includes a support contact surface 1021, an outer surface 1022’, and an inner surface 1023. Such portion of the support portion 102B has a smaller wall thickness H1 (i.e., a thickness between the outer surface 1022’ and the inner surface 1023). In order to reduce the process FMEA risk by complying with the injection moulding material DFM guidelines, the wall thickness H1 should be no less than a predetermined thickness threshold.

As shown in FIGS. 4A-4B, the lower edge 2011 of the inner wall 201 of the capture 101 is higher than the support contact surface 1021 of the support portion 102(102B) in the direction perpendicular to the support contact surface 1021 of the support portion 102(102B), so that when the package assembly 1043 having the substrate 104 or the substrate 104 is received in the receiving space formed by the captures 101 and the support portion 102(102B), for example, to the support contact surface 1021, the inner wall 201 is not in contact with the lower edge portions 2031, 2041 (see FIG. 2A) of the side surfaces of the substrate 104. The lower edge 2011 of the inner wall 201 is higher than the support contact surface 1021 by a first distance D1. The first distance D1 is greater than the height of the lower edge portions 2031, 2041 of the side surfaces of the substrate 104, e.g., in the direction perpendicular to the support contact surface 1021 of the support portion 102B, thereby ensuring that the inner wall 201 is not in contact with the lower edge portions 2031, 2041 of the side surfaces of the substrate 104.

On the same side of the pocket of the tray structure, in the direction perpendicular to the inner wall 201 of the capture 101, the outer edge 2061 of the support contact surface 1021 of the support portion 102(102B) is separated by a second distance D2 from the inner wall 201 and is located closer to the center of the receiving space 105 than the inner wall 201. The second distance D2 is greater than the width of the outer edge portion 2051 of the bottom surface 205 of the substrate 104, e.g., in the direction perpendicular to the inner wall 201 of the capture 101, thereby ensuring that the support contact surface 1021 is not in contact with the outer edge portion 2051 of the bottom surface 205 of the substrate 104 (see FIGS. 2C-2D).

As shown in FIG. 4B, with the arrangement that the lower edge 2011 of the inner wall 201 of the capture 101 is higher than the support contact surface 1021 of the support portion 102(102B) by a first distance D1, and the outer edge 2061 of the support contact surface 1021 of the support portion 102(102B) is separated by a second distance D2 from the inner wall 201 and is located closer to the center of the receiving space 105 than the inner wall 201, no conner edge is formed by the inner wall 201 and the support contact surface 1021. Instead, a conner edge relief, annotated in dashed circle, is formed between the capture 101 and the support portion 102(102B) faced with each other at the same side of the receiving space 105 so that the capture 101 and the support portion 102(102B) would not contact with an outer edge portion of the bottom of the substrate 104.

The support contact surface 1021 shown in FIGS. 4A-4B is a horizontal surface, and the inner wall 201 is a vertical surface, so that the direction perpendicular to the support contact surface 1021 is a vertical direction and the direction perpendicular to the inner wall 201 is a horizontal direction. In other embodiments, the support contact surface 1021 and the inner wall 201 include surfaces in other appropriate directions.

FIG. 5A shows a sectional view of a second embodiment of a tray structure, i.e., a tray structure 120, of the present disclosure after movement of a package assembly 1043 having a substrate 104, FIG. 5B is a first partially enlarged view of a part, indicated by a right circle, of the tray structure 120 shown in FIG. 5A, and FIG. 5C is a second partially enlarged view of a part, indicated by a left circle, of the tray structure 120 shown in FIG. 5A. The section lines of the sectional view in FIGS. 5A -5C pass through the capture 101 and the portion of the support portion 102(102B) having the depression 1024 facing the capture 101.

As described above, the receiving space 105 is configured to have a size slightly larger than the package assembly 1043 and the substrate 104 to receive the package assembly 1043 and the substrate 104. After the package assembly 1043 having the substrate 104 or the substrate 104 is received in the receiving space 105, the package assembly 1043 or the substrate 104 may move along the support contact surface 1021 of the support portion 102B during use (e.g., transporting) or in other applications.

As shown in FIG. 5A, as the package assembly 1043 having the substrate 104 moves along the support contact surface 1021 in a direction X, one of the captures 101 (a capture 101 on the right) comes into contact with a first side surface 501 of the substrate 104, while another of the captures 101 (a capture 101 on the left) is separated from a second side surface 502 of the substrate 104 opposite to the first side surface 501. In this case, the support portion 102B is still not in contact with the outer edge portion 2051 of the bottom surface 205 of the substrate 104. The bottom surface 205 of the substrate 104 is arranged with solder balls 1044. In other embodiments, the bottom surface 205 of the substrate 104 is arranged with other suitable structures.

As shown in FIG. 5B, the inner wall 201 of the one of the captures 101 of the pocket of the tray structure 120 is in contact with a part of the first side surface 501 of the substrate 104 but not in contact with a lower edge portion 5011 of the first side surface 501 of the substrate 104. In the direction perpendicular to the support contact surface 1021 of the support portion 102B, e.g., in the vertical direction, the inner wall 201 is higher than the support contact surface 1021 by a distance, so that the inner wall 201 is not in contact with the lower edge portion 5011 of the first side surface 501 of the substrate 104.

The support contact surface 1021 of the support portion 102B is in contact with a part of the bottom surface 205 of the substrate 104 but not in contact with the outer edge portion 2051 of the bottom surface 205 of the substrate 104. On the same side of the pocket of the tray structure, in the direction perpendicular to the inner wall 201, e.g., in the horizontal direction, the outer edge 2061 of the support contact surface 1021 is separated by a third distance from the inner wall 201 and is located closer to the center of the receiving space 105 than the inner wall 201, so that the support contact surface 1021 is not in contact with the outer edge portion 2051 of the bottom surface 205 of the substrate 104. The third distance is greater than the width of the outer edge portion 2051 of the bottom surface 205 of the substrate 104.

As shown in FIG. 5C, the another of the captures 101 of the pocket of the tray structure 120 is separated by a fourth distance from the second side surface 502 of the substrate 104. In this case, the support contact surface 1021 of the support portion 102B is still not in contact with the outer edge portion 2051 of the bottom surface 205 of the substrate 104. In the direction perpendicular to the inner wall 201, e.g., in the horizontal direction, the outer edge 2061 of the support contact surface 1021 is separated by a fifth distance from the inner wall 201 and is located closer to the center of the receiving space 105 than the inner wall 201. The outer edge 2061 of the support contact surface 1021 is separated by a sufficient distance from the inner wall 201 so that the outer edge 2061 is in contact with an interior of the bottom surface 205 of the substrate 104 but not in contact with the outer edge portion 2051 of the bottom surface 205 of the substrate 104. The interior of the bottom surface 205 of the substrate 104 is located closer to the center of the bottom surface 205 of the substrate 104 than the outer edge portion 2051. The fifth distance is greater than the sum of the fourth distance and the width of the outer edge portion 2051 of the bottom surface 205 of the substrate 104.

As shown in FIGS. 5B-5C, the inner surface 1023 of the support portion 102B is close to, but does not contact, the solder balls 1044 arranged on the bottom surface 205 of the substrate 104. The sectional views of the tray structure 120 shown in FIGS. 5A-5C can also be sectional views of the tray structure 120 when the package assembly 1043 having the substrate 104 is received in the receiving space 105.

As previously described, a plurality of solder balls (see FIGS. 5A-5C) are arranged on the bottom surface 205 of the substrate 104 for a BGA type of substrate package assembly, and a plurality of land pads (not shown) are arranged on the bottom surface of the substrate 104 for an LGA type of substrate package assembly. As shown in FIG. 5B, structures, such as solder balls, land pads, and the like, arranged on the bottom surface 205 of the substrate 104 are spaced apart from the outer edge 2051 of the bottom surface 205 by a predetermined spacing S. In order to avoid damage to these structures of the bottom surface 205 of the substrate 104 due to contacting the support frame structures (e.g., the support frames 102A, 102B, and 102C) of the support portion 102, these structures of the bottom surface 205 of the substrate 104 need to be spaced apart from the inner surface 1023 of the support frame by a distance S1. Also, in order to avoid the support frame from contacting the outer edge portion 2051 of the bottom surface 205 of the substrate 104, the outer edge 2061 of the support contact surface 1021 of the support frame needs to be spaced apart from the outer edge portion 2051 of the bottom surface 205 of the substrate 104 by a distance S2, e.g., in a direction perpendicular to the inner wall 201 of the capture 101.

As shown in FIGS. 4A-4B, when the predetermined spacing S between the structure arranged on the bottom surface 205 of the substrate 104 and the outer edge 2051 of the bottom surface 205 is small, the thickness H of the support contact surface 1021 of the support frame needs to be designed small in order to satisfy the above-mentioned needs and to take into account the dimension variance of the pocket of the tray structure and the substrate. In this case, the wall thickness H2 of the portion of the support portion 102B that does not have the depression 1024 facing the capture 101 (i.e., the thickness between the outer surface 1022 and the inner surface 1023) is still larger, which meets the injection moulding material DFM guidelines to reduce the process FMEA risk. The wall thickness H1 (i.e., the thickness between the outer surface 1022’ and the inner surface 1023) of the portion of the support portion 102B having the depression 1024 facing the capture 101 is correspondingly smaller. When the above spacing S is sufficiently small such that the wall thickness H1 between the inner surface 1023 and the outer surface 1022’ of the support frame is less than a predetermined thickness threshold (e.g., 0.50 mm), the tray structure will not comply with the injection moulding material DFM guidelines, thus increasing the process FMEA risk.

The fifth embodiment of the tray structure designed in the present disclosure, i.e., the tray structure 150, is capable of solving the above problems. As previously described, the support portion 102D of the pocket of the tray structure 150 comprises a plurality of projections 1027, 1028 spaced apart. The projections 1027, 1028 are arranged along a circumferential direction and are spaced apart from the plurality of captures 101 along the circumferential direction. On the same side of the pocket of the tray structure, in the direction perpendicular to the inner wall 201 of the capture 101, the projections 1027, 1028 do not face the captures 101.When the predetermined spacing S between the structure arranged on the bottom surface 205 of the substrate 104 and the outer edge 2051 of the bottom surface 205 is small, the thickness H of the support contact surface 1021 of the support frame needs to be designed small. However, the wall thickness of the projections 1027, 1028 of the support portion 102D, which is substantially the same as the thickness H2 of the support portion 102B, is still larger because the outer surface 1022 includes an upper portion 301 which is tilted gradually away from the receiving space 105 in the top-to-bottom direction (see FIG. 3A). Thus, the projections 1027, 1028 of the support portion 102D of the pocket enable the tray structure to meet the injection moulding material DFM guidelines without increasing the process FMEA risk.

Although the present disclosure is described in conjunction with the examples of embodiments outlined above, various alternatives, modifications, variations, improvements, and/or substantial equivalents that are known or current or to be anticipated before long may be obvious to those of at least ordinary skill in the art. In addition, the technical effects and/or technical problems described in this specification are exemplary rather than limiting. Therefore, the disclosure in this specification may be used to solve other technical problems and have other technical effects and/or may solve other technical problems. Accordingly, the examples of the embodiments of the present disclosure as set forth above are intended to be illustrative rather than limiting. Various changes can be made without departing from the scope of the present disclosure. Therefore, the present disclosure is intended to include all known or earlier developed alternatives, modifications, variations, improvements and/or basic equivalents.

1. A tray structure, comprising:
one or more pockets, each pocket configured to receive a package assembly having a substrate or to receive a substrate, each pocket comprising:
a plurality of captures configured to be in contact with side surfaces of the substrate; and
a support portion configured to support the substrate,
wherein the captures and the support portion form a receiving space to receive at least a part of the substrate, the captures are configured to be in contact with parts of the side surfaces of the substrate above lower edge portions thereof, and the support portion is configured to be in contact with a part of a bottom surface of the substrate but not in contact with an outer edge portion of the bottom surface of the substrate.

2. The tray structure according to claim 1, wherein the captures comprise inner walls configured to be in contact with the side surfaces of the substrate, and lower edges of the inner walls are higher than a surface of the support portion that supports the substrate.

3. The tray structure according to claim 2, wherein the support portion comprises a support contact surface configured to be in contact with a part of the bottom surface of the substrate, and an outer edge of the support contact surface is located closer to a center of the receiving space than the inner walls.

4. The tray structure according to claim 1, wherein the captures and the support portion are configured such that when the substrate moves along a surface of the support portion that supports the substrate in the receiving space until one of the captures comes into contact with a first side surface of the substrate and another of the captures is separated from a second side surface of the substrate opposite to the first side surface, the support portion is still not in contact with the outer edge portion of the bottom surface of the substrate.

5. The tray structure according to claim 1, wherein an outer surface of the support portion away from the receiving space is in the shape of a slope.

6. The tray structure according to claim 1, wherein the support portion is made of a soft or hard material.

7. The tray structure according to claim 1, wherein the support portion is:
a support frame configured to be in contact with a peripheral portion of the bottom surface of the substrate to support the substrate; or
a support floor configured to be in contact with substantially the entire bottom surface of the substrate to support the substrate.

8. The tray structure according to claim 7, wherein the support frame comprises a plurality of projection portions which are disposed along a circumferential direction and separated from the plurality of captures along the circumferential direction.

9. The tray structure according to claim 1, wherein the tray structure further comprises:
a mounting frame on which the plurality of captures and the support portion are mounted.

10. A tray system, comprising one or more tray structures according to claim 1.

11. The tray system according to claim 10, wherein the tray structures are stacked on top of one another.
